(19) United States
(12) Patent Application Publication
(10) Pub. No.: US 2008/0118338 A1
(43) Pub. Date: May 22, 2008

(54) TRANSFER ROBOT

(75) Inventors: HUNG-KAI HUANG, Chu-Nan (TW); KAI-JEN CHENG, Chu-Nan (TW)

Correspondence Address: PCE INDUSTRY, INC.;ATT. CHENG-JU CHIANG, 458 E. LAMBERT ROAD, FULLERTON, CA, 92835, US

(73) Assignee: FOXSEMICON INTEGRATED TECHNOLOGY, INC., Chu-Nan (TW)

(21) Appl. No.: 11/845,726

(22) Filed: Aug. 27, 2007

(30) Foreign Application Priority Data
Nov. 22, 2006 (CN) 200610156987.1

(51) Int. Cl. H01L 21/68; G06F 19/00

(52) U.S. Cl. 414/744.3; 700/245; 901/30

(57) ABSTRACT

A transfer robot (100) for transferring a silicon wafer includes a base support (110), an end-effector (130) having a main body (131) and two spaced fingers (132) extending from the main body, an articulated arm (120) assembly interconnecting the base support and the end-effector, a pair of first linear optical sensors (1331, 1332) arranged on the respective fingers of the end-effector, a second linear optical sensor (1333) arranged on the main body of the end-effector, and a plurality of displacement sensors (134) arranged non-collinearly on the end-effector, for ascertaining a vertical position and a leveling of the silicon wafer. The first and second linear optical sensors are arranged non-collinearly on the end-effector for ascertaining a center of the silicon wafer.

### BACKGROUND OF THE INVENTION

1. Field of the Invention

The present invention relates to transfer robot and, more particularly, to a transfer robot with an automatic calibration function.

2. Description of Related Art

In the fabrication of semiconductors, silicon wafers are usually held in a storage cassette and then moved to various process stations by a transfer system. The transfer system must be able to precisely pick up the silicon wafers from the storage cassette and then precisely transfer them to a designated process station or a plurality of process stations where the silicon wafers undergoes some processes, such as heating or alignment. During transfer, if the centers or the vertical position or the leveling of the silicon wafers are displaced, the silicon wafers may be damaged or dragged.

A conventional transfer robot with an automatic calibration function is used to detect the actual position of a silicon wafer and estimate whether the center of the silicon wafer has been displaced. However, the silicon wafer usually has a notch, and the conventional transfer robot is often influenced by the notch and is unable to accurately estimate whether the center of the silicon wafer has been displaced. Furthermore, the conventional transfer robot cannot detect the leveling of the silicon wafer such that the silicon wafer may easily impact with other objects, etc., and may be damaged during transfer.

What is needed, therefore, is a transfer robot with an automatic calibration function which can estimate whether the center or the leveling of the silicon wafer has been displaced so as to avoid damaging the silicon wafer.

### SUMMARY OF THE INVENTION

A transfer robot for transferring a silicon wafer according to a preferred embodiment, includes a base support, an end-effector having a main body and two spaced apart fingers extending from the main body, an articulated arm assembly interconnecting the base support and the end-effector, a pair of first linear optical sensors arranged on the respective fingers of the end-effector, a second linear optical sensor arranged on the main body of the end-effector, and a plurality of displacement sensors arranged non-collinearly on the end-effector, for ascertaining a vertical position of the silicon wafer. The first and second linear optical sensors are arranged non-collinearly on the end-effector for ascertaining a position of a center of the silicon wafer.

A method for transferring a silicon wafer according to another preferred embodiment, includes the steps of:

providing a transfer robot as claimed in claim 1;
determining a desired horizontal location of the center of the silicon wafer, using the first linear optical sensors;
determining a desired vertical location and a desired leveling of the silicon wafer, using at least one of the displacement sensors;
determining an actual horizontal location of the center of the silicon wafer, using the first and second linear optical sensors;
determining an actual vertical location and an actual leveling of the silicon wafer, using the displacement sensors;
comparing the desired location of the center of the silicon wafer with the actual location of the center thereof to determine whether the actual center of the silicon wafer has been displaced;
comparing the desired vertical location of the silicon wafer and the actual vertical location thereof to determine whether the vertical position of the silicon wafer has been displaced;
comparing the desired leveling of the silicon wafer and the actual level thereof to determine whether the leveling of the silicon wafer has been displaced;
calibrating position of the end-effector if at least one of the actual location of the center, the vertical position and the leveling of the silicon wafer is displaced; and
transferring the silicon wafer.

The present transfer robot and method employ a plurality of optical sensors to accurately ascertain the actual horizontal location of the center of the silicon wafer and estimate whether the actual horizontal location of the center of the silicon wafer is displaced, and employ a plurality of displacement sensors to accurately ascertain the vertical position and the leveling of the silicon wafer and estimate whether the vertical position and/or leveling of the silicon wafer is displaced. Therefore, the present transfer robot can efficiently avoid damaging the silicon wafer in transfer.

Other advantages and novel features of the present invention will become more apparent from the following detailed description of preferred embodiment when taken in conjunction with the accompanying drawings, in which:

### BRIEF DESCRIPTION OF THE DRAWINGS

Many aspects of the present transfer robot for transferring a silicon wafer can be better understood with reference to the following drawings. The components in the drawings are not necessarily drawn to scale, the emphasis instead being placed upon clearly illustrating the principles of the present transfer robot. Moreover, in the drawings, like reference numerals designate corresponding parts throughout the several views.

FIG. 1 is a exploded, isometric view of a transfer robot according to a preferred embodiment of the present invention;

FIG. 2 is a exploded, isometric view of an end-effector of the transfer robot of FIG. 1;

FIG. 3 is a flow chart of a method for transferring a silicon wafer using the transfer robot of FIG. 1;

FIG. 4 is a schematic, side-on view of the transfer robot showing first reference points on an aligner;

FIG. 5 is a schematic, side-on view of the transfer robot showing a second reference point on the aligner;

FIG. 6 is a schematic, side-on view of the transfer robot using the pair of first linear optical sensors to sense the silicon wafer on the aligner;

FIG. 7 is a schematic view of the transfer robot calculating the actual horizontal location of the center of the silicon wafer;

FIG. 8 is a schematic, side-on view of the transfer robot using the second linear optical sensor to sense the silicon wafer on the aligner;

FIG. 9 is a schematic, side-on view of the transfer robot transferring the silicon wafer on the aligner;

FIG. 10 is a schematic, side-on view of the transfer robot showing first reference points on an cassette;

FIG. 11 is a schematic, side-on view of the transfer robot showing a second reference point on the cassette;

FIG. 12 is a schematic, side-on view of the transfer robot transferring the silicon wafer on the cassette;

FIG. 13 is a schematic, side-on view of a process station;

FIG. 14 is a schematic, side-on view of the transfer robot showing first reference points on the process station;

FIG. 15 is a schematic, side-on view of the transfer robot showing a second reference point to the process station; and

FIG. 16 is a schematic, side-on view of the transfer robot transferring the silicon wafer to the process station.

### DETAILED DESCRIPTION OF THE INVENTION

Reference will now be made to the drawings to describe a preferred embodiment of the present transfer robot with an automatic calibration function in detail.

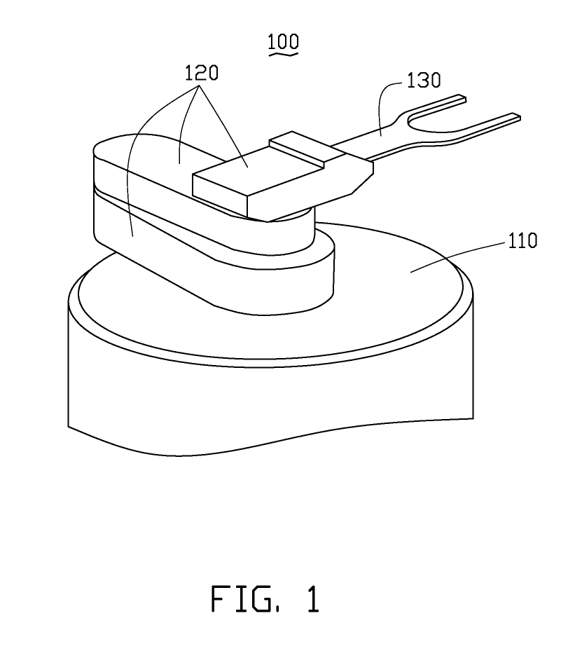

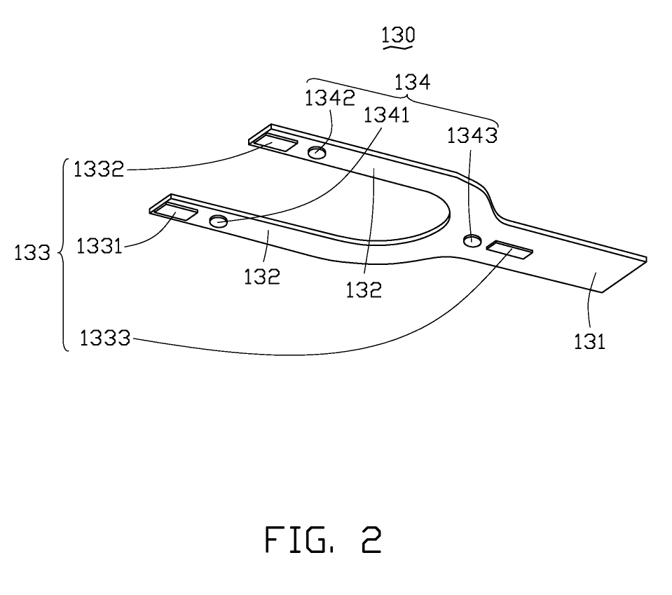

Referring to FIGS. 1 and 2, a transfer robot 100 with an automatic calibration function in accordance with a preferred embodiment, includes a base support 110, an end-effector 130 having a main body 131 and two spaced apart fingers 132 extending from the main body 131, an articulated arm 120 assembly interconnecting the base support 110 and the end effector 130, a plurality of optical sensors 133 arranged on the end-effector 130, and a plurality of displacement sensors 134 arranged on the end-effector 130.

The end-effector 130 is configured (i.e., structured and arranged) for supporting a silicon wafer. The articulated arm 120 assembly interconnects the base support 110 and the end-effector 130 for driving the end-effector 130 in three-dimensional directions. The plurality of optical sensors 133 are arranged non-collinearly on the end effector 130. The plurality of displacement sensors 134 are also arranged non-collinearly on the end effector 130.

The base support 110 includes a micro processing unit (not shown) and a driver (not shown) therein. In operation, the micro processing unit receives feedback signals from the optical sensors 133 and the displacement sensors 134, and then outputs a controlling signal to the driver. The driver drives the articulated arm 120 according to the received controlling signal, in this way the end-effector 130 is moved to a desired location.

The end-effector 130 includes a main body 131 connected with the articulated arm assembly 120 and two spaced apart fingers 132 extending from the main body 131. In this exemplary embodiment, the end-effector 130 is Y-shaped with two spaced fingers 132. Alternatively, the fingers 132 may be V-shaped, U-shaped or any other suitable shape.

The plurality of optical sensors 133 includes a pair of first linear optical sensors 1331, 1332 arranged on the respective finger 132, and a second linear optical sensors 1333 arranged on the main body. The pair of first linear optical sensors 1331, 1332 and the second linear optical sensors 1333 are arranged non-collinearly on the end-effector 130 for ascertaining a center of the silicon wafer. Preferably, the pair of first linear optical sensors 1331, 1332 should be arranged in a straight line perpendicular to a lengthwise direction of the end-effector 130 and cooperate with the second linear optical sensor 1333 for avoiding interference with a notch of the silicon wafer. Preferably, the pair of first linear optical sensors 1331, 1332 and the second linear optical sensor 1333 are arranged to form an isosceles triangle.

The plurality of optical sensors 133 may be sensors with a mode of detecting natural light. The optical sensors 133 can receive the natural light, and if the natural light is detected at a location, the optical sensors 133 will sense the location to obtain information of the location and feedback the information to the base support 110. The plurality of optical sensors 133 may be also sensors with a mode of reflecting emitting light. That is, the optical sensors 133 can emit light, and if the emitting light is reflected at a location, the optical sensors 133 will sense the location to obtain information of the location and feedback the information to the base support 110. The plurality of optical sensors 133 are configured for ascertaining the center of the silicon wafer.

The plurality of displacement sensors 134 are arranged non-collinearly on the end-effector 130. Preferably, the plurality of displacement sensors 134 includes three displacement sensors 1341, 1342 and 1343. In this exemplary embodiment, the displacement sensors 1341, 1342 are arranged on the respective fingers 132 and near to the pair of first linear optical sensors 1331, 1332 respectively. The displace sensor 1343 is arranged on the main body 131 and near to the second linear optical sensor 1333. Preferably, the three displacement sensors 1341, 1342 and 1343 are arranged to form an isosceles triangle.

The plurality of displacement sensors 134 may be noncontact mode sensors, which can measure a vertical distance of a sensing location by emitting light or sound wave, etc. The plurality of displacement sensors 134 are configured for ascertaining a vertical position and a leveling of the silicon wafer.

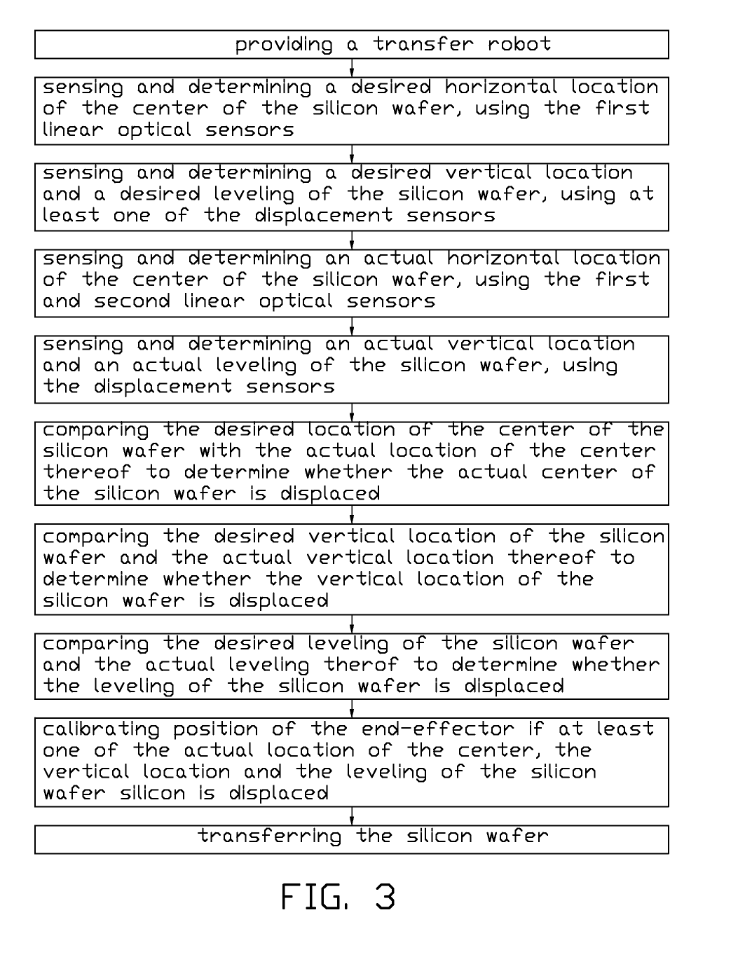

Referring to FIG. 3, a method for transferring a silicon wafer in accordance with a second preferred embodiment is shown. The method includes the flowing steps:

providing a transfer robot as described above;
determining a desired horizontal location of the center of the silicon wafer using the first linear optical sensors;
determining a desired vertical location and a desired leveling of the silicon wafer using at least one of the displacement sensors;
determining an actual horizontal location of the center of the silicon wafer using the first and second linear optical sensors;
determining an actual vertical location and an actual leveling of the silicon wafer using the displacement sensors;
comparing the desired location of the center of the silicon wafer with the actual location of the center thereof to determine whether the actual location of the center of the silicon wafer is displaced;
comparing the desired vertical location of the silicon wafer and the actual vertical location thereof to determine whether the vertical position of the silicon wafer is displaced;
comparing the desired leveling of the silicon wafer and the actual level thereof to determine whether the leveling of the silicon wafer is displaced;
calibrating the silicon wafer if at least one of the actual location of the center, the vertical position and the leveling of the silicon wafer is displaced; and
transferring the silicon wafer.

The method for transferring a silicon wafer in accordance with the preferred embodiment is described below.

### EXAMPLE 1

A method for transferring a silicon wafer 300 on an aligner 200 is provided.

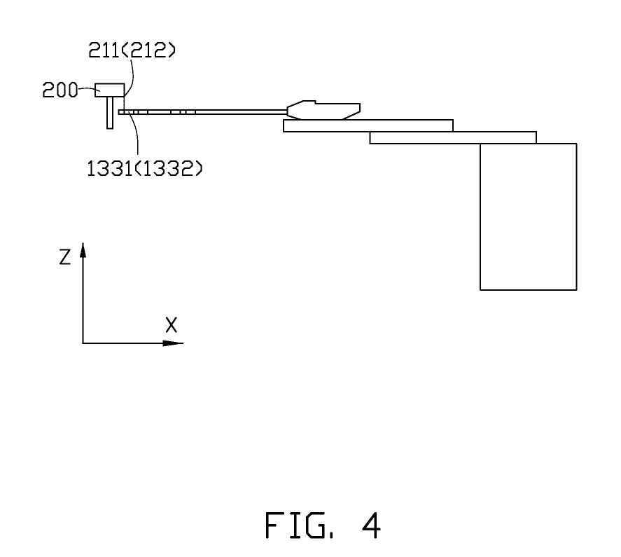

Referring to FIG. 4, a coordinate system is created with an initial position of the transfer robot 100 as an origin. The end-effector 130 of the transfer robot 100 begins to move. When the pair of first linear optical sensors 1331, 1332 are detected or reflected for the first time by two points 211, 212 at the periphery of the aligner 200, the two points 211, 212 are denoted as first reference points and the pair of first linear optical sensors 1331, 1332 sense the two first reference points 211, 212 to obtain information thereof and feedback the information into the micro processing unit of the base support 110. The micro processing unit calculates the center of the aligner 200 based on the information of the first reference point 211, 212 and known standard of the aligner 200, and the calculated center of the aligner 200 is a desired horizontal location of the center of the silicon wafer 300 if the silicon wafer 300 is placed on the aligner 200.

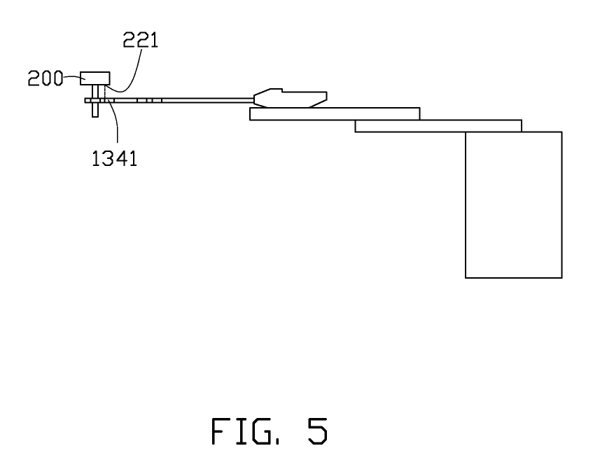

Referring to FIG. 5, the end-effector 130 of the transfer robot 100 continues to move, and uses at least one displacement sensor 1341 to sense a point 221 of the bottom surface of the aligner 200 serving as a second reference point. The at least one displacement sensor 1341 obtains the vertical location of the second reference point 221 and feeds the vertical location into the micro processing unit of the base support 110. The processing unit calculates a desired vertical location of the silicon wafer 300, based on the feedback vertical location of the second reference point 221 of the aligner 220 and the known standard of the aligner 220.

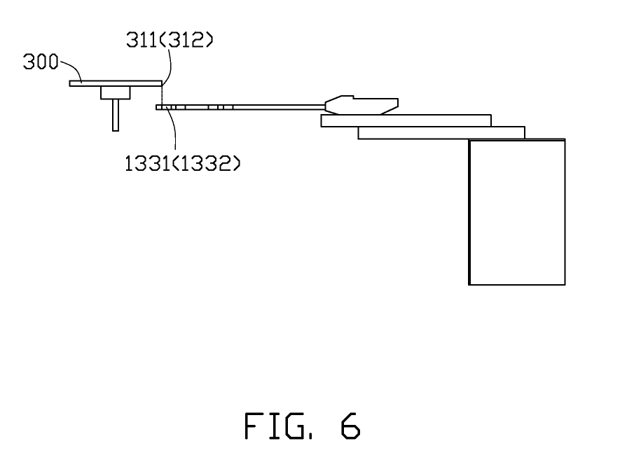

Referring to FIG. 6, when the silicon wafer 300 is actually placed on the aligner 200, the end-effector 130 of the transfer robot 100 begins to move to calculate the actual horizontal location of the center of the silicon wafer 300. When the pair of first linear optical sensors 1331, 1332 are detected or reflected for the first time by two points 311, 312 of the periphery of the silicon wafer 300, the pair of first linear optical sensors 1331, 1332 sense the two points 311, 312 to obtain information thereof and feedback the information into the micro processing unit. The micro processing unit processes the information of the two points 311, 312 to estimate whether one of the two point 311, 312 is arranged on the notch.

Since the pair of first linear optical sensors 1331, 1332 are arranged in a straight line perpendicular to the lengthwise direction of the fingers 132, the pair of first linear optical sensors 1331, 1332 are arranged at locations having essentially identical lengthwise positions. Furthermore, the silicon wafer 300 generally has only one notch thereon, so that if the two point 311, 312 sensed by the first linear optical sensors 1331, 1332 have the same lengthwise position, the two point 311, 312 are not placed on the notch of the silicon wafer 300; and if the two point 311, 312 sensed by the first linear optical sensors 1331, 1332 have different lengthwise positions, one of the two point 311, 312 is placed on the notch of the silicon wafer 300. The notch of the silicon wafer 300 is generally placed inwards, therefore, if the point 311 has a lengthwise coordinate bigger than that of the point 312, the point 311 is placed on the notch.

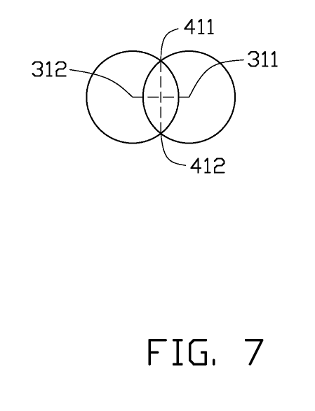

Referring to FIG. 7, if the two points 311, 312 are both not placed on the notch of the silicon wafer 300, the micro processing unit processes the information of the two point 311, 312 and calculates the actual horizontal location of the center of the silicon wafer 300. The method of calculating the actual horizontal location of the center of the silicon wafer 300 includes following steps: making two circles by using the two points 311, 312 as centers of the two circles respectively, and using the known radius of the silicon wafer 300 as a radius such that the two circles intersect at two points 411, 412; selecting a point where the two circles intersect, such as the point 411, which is near to the desired location of the center of the silicon wafer 300, to serve as an actual horizontal location of the center of the silicon wafer 300 placed on the actual horizontal location, because the actual location of the center of the silicon wafer 300 placed on the actual horizontal location is not far away from the desired horizontal location of the center of the silicon wafer 300 placed on the desired horizontal location.

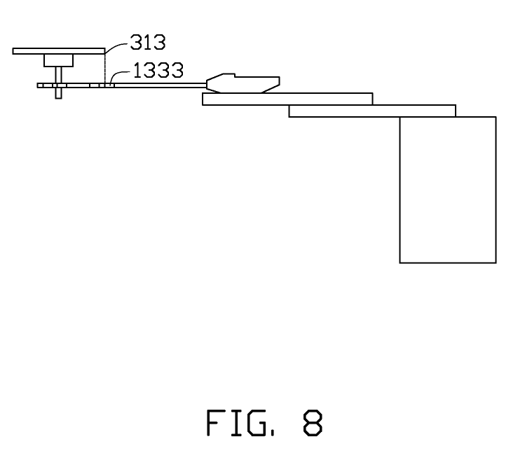

Referring to FIG. 8, if one of the two point 311, 312 is placed on the notch of the silicon wafer 300, the end-effector 130 of the transfer robot 100 continues to move. When the second linear optical sensor 133 are detected or reflected for the first time by one point 313 of the periphery of the silicon wafer 300, the second linear optical sensors 1333 sense the point 313 to obtain information thereof and feedback the information into the micro processing unit. Since the silicon wafer 300 generally has only one notch thereon, the point 313 cannot be placed on the notch of the silicon wafer 300. The micro processing unit process the information of the three point 311, 312 and 313 to select two point not placed on the notch of the silicon wafer 300 and calculate the actual horizontal location of the center of the silicon wafer 300 described as the above.

When the end-effector 130 moves, the three displacement sensors 1341, 1342 and 1343, which are arranged non-collinearly, sense and calculate actual vertical locations of any three points of the silicon wafer 300 respectively. The three points of the silicon wafer 300 sensed by the three displacement sensors 1341, 1342 and 1343, should be arranged non-collinearly, so the micro processing unit can determine the vertical displacement of the silicon wafer 300 based on the actual vertical locations of the three points of the silicon wafer 300.

The micro processing unit compares the desired horizontal location of the center of the silicon wafer 300 with the actual horizontal location of the center of the silicon wafer 300 to determine whether the actual horizontal location of the center of the silicon wafer is displaced. Furthermore, the micro processing unit compares the desired vertical location of the silicon wafer 300 and the actual vertical location thereof to estimate whether the vertical position of the silicon wafer 300 is displaced.

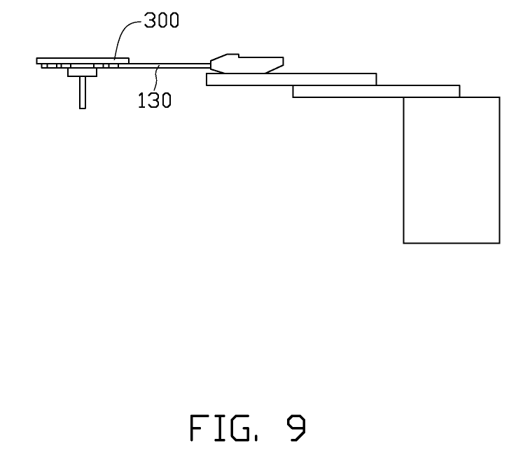

Referring to FIG. 9, if the micro processing unit determines the actual horizontal location of the center of the silicon wafer 300 or the vertical position thereof is displaced, the micro processing unit will send out an alarm and the system will stop to avoid the silicon wafer 300 damaging. If the micro processing unit determines both of the actual horizontal location of the center and the lever degree of the silicon wafer 300 have not been displaced, the transfer robot transfers the silicon wafer 300.

### EXAMPLE 2

A method for transferring silicon wafers 1 to 25 in a cassette 500 is provided.

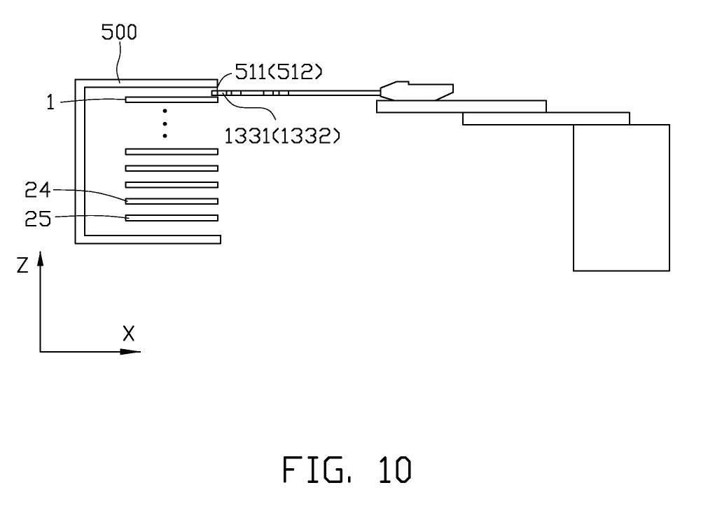

The method of example 2 is similar to that of example 1. Referring to FIG. 10, the silicon wafers 1 to 25 are placed in the cassette 500. The pair of first linear optical sensors 1331, 1332 are used to sense the periphery of the cassette 500. When the pair of first linear optical sensors 1331, 1332 are detected or reflected for the first time by two point 511, 512 of the periphery of the cassette 500, the two point 511, 512 are designed as first reference points and the pair of first linear optical sensors 1331, 1332 sense the two first reference points 511, 512 to obtain information thereof and feedback the information into the micro processing unit. The micro processing unit calculates the desired horizontal location of the centers of each of the silicon wafers 1 to 25 based on the first reference point 511, 512 and the known standard of the cassette 500.

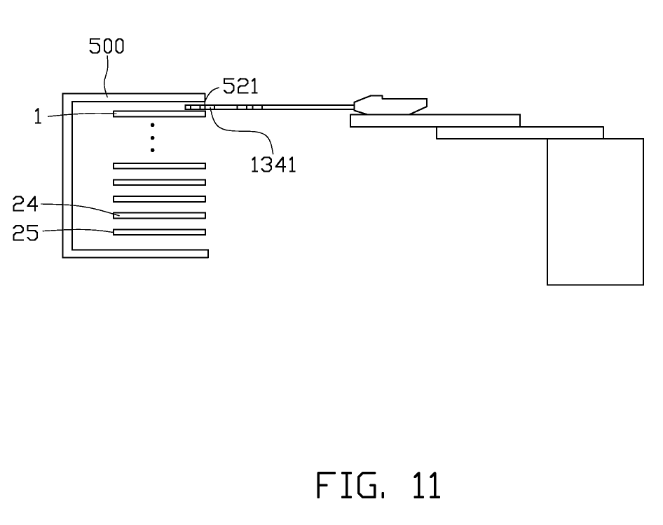

Referring to FIG. 11, at least one displacement sensor 1341 is used to sense any point 521 of the inner surface of the top portion of the cassette 500 and assign the point 521 as a second reference point to obtain a desired vertical location of each of the silicon wafer 1 to 25 based on the feedback vertical location of the second reference point 521 and the known standard of the cassette 500.

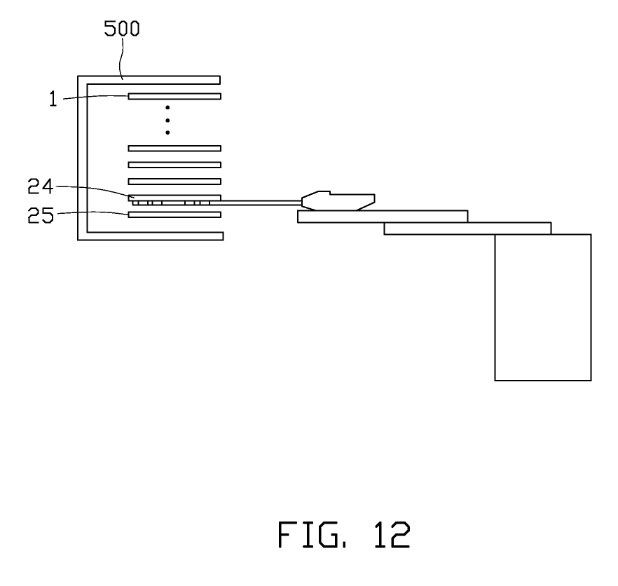

Referring to FIG. 12, when the transfer robot 100 is used to transfer the silicon wafer 24, the micro processing unit calculates the desired horizontal location of the center and the desired vertical location of the silicon wafer 24 based on the first reference points 511, 512, the second reference point 521 and the known the standard of cassette. The micro processing unit moves the end-effector 130 of the transfer robot 100 under the silicon wafer 24, and uses the three optical sensors to calculate the actual horizontal location of the center of the silicon wafer 24 and uses the three displacement sensors to calculate the actual vertical location of the silicon wafer 24 described as the above. Then the micro processing unit compares the desired horizontal location of the center of the silicon wafer 24 with the actual horizontal location of the center to determine whether the actual horizontal location of the center of the silicon wafer 24 defects, and compares the desired vertical location of the silicon wafer 24 with the actual vertical location to determine whether the vertical position of the silicon wafer 24 has been displaced.

The transfer robot can precisely estimate whether the actual horizontal location of the center or the lever degree of the silicon wafer is displaced, to avoid the silicon wafer being damaged.

### EXAMPLE 3

A method for transferring a silicon wafer 700 on a process station or a buffer station is provided.

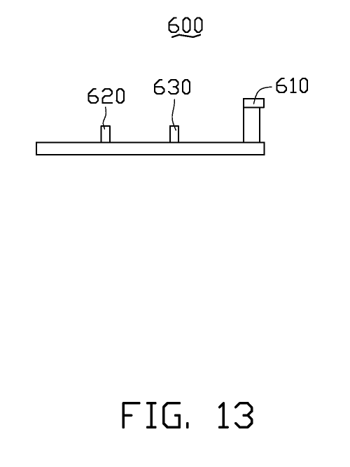

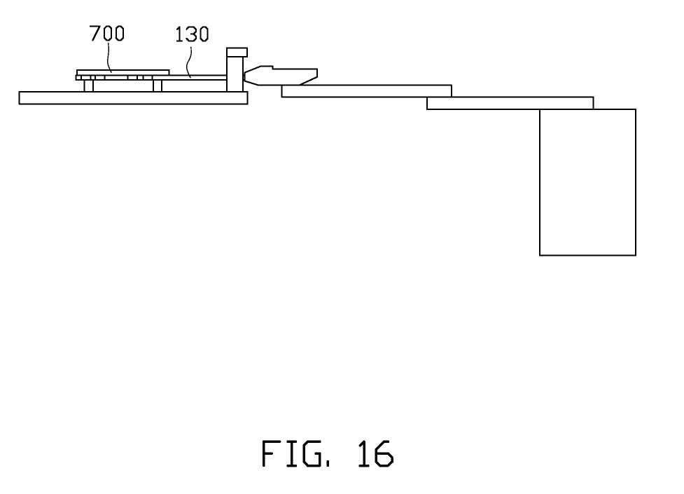

The method of example 3 is similar to that of example 1. Referring to FIGS. 13 to 16, the silicon wafer 700 should be placed in the process station 600. Referring to FIG. 13, the process station 600 includes a gate 610 configured (i.e., structured and arranged) for inserting the end-effector 130 into the process station 600, and two supporting block 620, 630 configured for placing the silicon wafer 700.

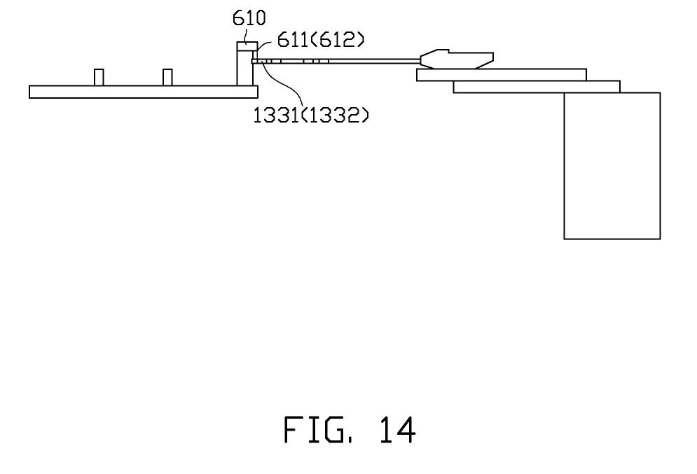

Referring to FIG. 14, the pair of first linear optical sensors 1331, 1332 are used to sense the periphery of the gate 610 of the process station 600. When the pair of first linear optical sensors 1331, 1332 are detected or reflected for the first time by two point 611, 612 of the periphery of the gate 610, the two point 611, 612 are designed as first reference points to calculates the desired horizontal location of the center of the silicon wafer 700 based on the known standard of the process station 600.

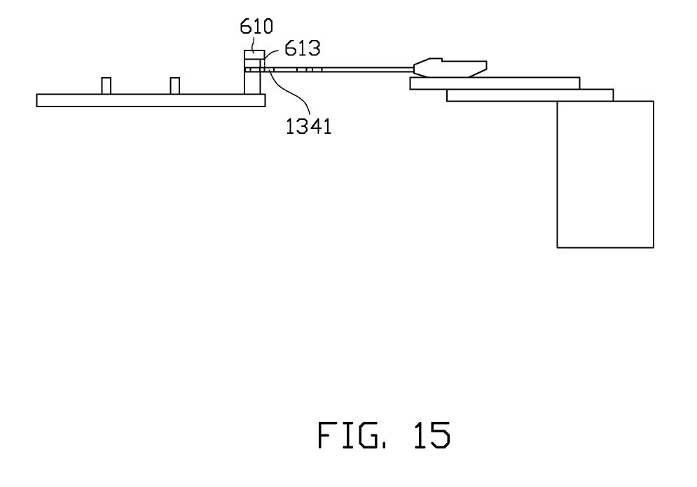

Referring to FIG. 15, at least one displacement sensor 1341 is used to sense any point 613 of the bottom surface of the gate 610 and design the point 613 as a second reference point to obtain a desired vertical location for the silicon wafer 700.

Since the silicon wafer 700 generally is not displaced on the processing station 600 or the buffer station, the desired horizontal location of the center and the desired vertical location of the silicon wafer 700 can be considered as the actual horizontal location of the center and the actual vertical location of the silicon wafer 700.

Of course, the transfer robot 100 can also measure the actual horizontal location of the center and the actual location of the silicon wafer 700 on the process station 600 or the buffer station to estimate whether the silicon wafer 700 is displaced.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A transfer robot for transferring a silicon wafer, comprising:
a base support;
an end-effector having a main body and two spaced apart fingers extending from the main body;
an articulated arm assembly interconnecting the base support and the end-effector;
a pair of first linear optical sensors arranged on the respective fingers of the end-effector;
a second linear optical sensor arranged on the main body of the end-effector, the first and second linear optical sensors being arranged non-collinearly on the end-effector for ascertaining a center of the silicon wafer; and
a plurality of displacement sensors arranged non-collinearly on the end-effector, for ascertaining a vertical position and a leveling of the silicon wafer.

2. The transfer robot as claimed in claim 1, wherein the pair of first linear optical sensors are arranged on a straight line perpendicular to a lengthwise direction of the end-effector.

3. The transfer robot as claimed in claim 2, wherein the first and linear optical sensors are arranged to form an isosceles triangle.

4. The transfer robot as claimed in claim 3, wherein the plurality of displacement sensors comprises three displacement sensors arranged to form an isosceles triangle.

5. The transfer robot as claimed in claim 1, wherein the end-effector comprises a main body connecting with the articulated arm and two spaced fingers extending from the main body.

6. The transfer robot as claimed in claim 1, wherein the plurality of optical sensors are selected from a group consisting of sensors with a mode of detecting natural light and sensors with a mode of reflecting emitting light.

7. A method for transferring a silicon wafer, comprising:
providing a transfer robot as claimed in claim 1;
determining a desired horizontal location of the center of the silicon wafer, using the first linear optical sensors;
determining a desired vertical location and a desired leveling of the silicon wafer, using at least one of the displacement sensors;
determining an actual horizontal location of the center of the silicon wafer, using the first and second linear optical sensors;
determining an actual vertical location and an actual leveling of the silicon wafer, using the displacement sensors;
comparing the desired location of the center of the silicon wafer with the actual location of the center thereof to determine whether the actual center of the silicon wafer is displaced;
comparing the desired vertical location of the silicon wafer and the actual vertical location thereof to determine whether the vertical position of the silicon wafer is displaced;
comparing the desired leveling of the silicon wafer and the actual leveling thereof to determine whether the leveling of the silicon wafer is displaced;
calibrating position of the end-effector if at least one of the actual location of the center, the vertical position and the leveling of the silicon wafer silicon is displaced; and
transferring the silicon wafer.

8. The method as claimed in claim 7, wherein the first linear optical sensors are arranged on a straight line perpendicular to a lengthwise direction of the end-effector.
